(19) United States
(12) Patent Application Publication
(10) Pub. No.: US 2026/0313854 A1
(43) Pub. Date: Oct. 8, 2026

(54) GAS-LIQUID PHASE CHANGE CARBON DIOXIDE ENERGY COMPREHENSIVE UTILIZATION SYSTEM ADAPTED FOR DATA CENTER

(71) Applicant: Exax Energy Technology (Shenzhen) Co., Ltd, Shenzhen (CN)

(72) Inventors: Hui KANG, Shenzhen (CN); Zihao TIAN, Shenzhen (CN); Lei WANG, Shenzhen (CN); Heng WANG, Shenzhen (CN); Xiaojiao JI, Shenzhen (CN)

(21) Appl. No.: 19/192,368

(22) Filed: Apr. 29, 2025

Related U.S. Application Data
(63) Continuation of application No. PCT/CN2025/087447, filed on Apr. 7, 2025.

(51) Int. Cl. H05K 7/20

(52) U.S. Cl. CPC H05K 7/20818

(57) ABSTRACT

Provided are a gas-liquid phase change carbon dioxide energy comprehensive utilization system adapted for a data center and a control method therefor. The system includes: an energy storage subsystem, the data center, and a heat balance component. The energy storage subsystem includes a gaseous carbon dioxide management unit, an energy storage component, a liquid storage unit, and an energy release component, which are sequentially connected in that order to form a closed loop. The energy release component includes an evaporator. A heat exchange medium inlet of the data center is connected to a heat exchange medium outlet of the evaporator, and a heat exchange medium outlet of the data center is connected to a heat exchange medium inlet of the evaporator. The heat balance component includes a high-temperature transmission pipeline and a low-temperature transmission pipeline.

### TECHNICAL FIELD

The present disclosure relates to the field of energy storage and power generation technologies, and particularly to a gas-liquid phase change carbon dioxide energy comprehensive utilization system adapted for a data center and a control method therefor.

### BACKGROUND

With the growth of computing power, a data center is gradually becoming a major energy consumer. On one hand, the data center has a continuous and stable power demand. On the other hand, the data center also generates a huge heat dissipation demand due to chip heat dissipation.

Although the use of green power sources such as wind power and photovoltaic power can reduce electricity costs, a power generation time of these two types of green power sources is greatly affected by an environmental and is unstable, thereby making these two types of green power sources impossible to provide a stable power supply for the data center. Moreover, when there is no wind or solar energy, commercial power is still needed, which does not significantly reduce electricity costs. In addition, to meet the huge heat dissipation demand of the data center, cooling equipment for heat dissipation of the data center also consumes a large amount of electricity, and the construction investment cost of the cooling equipment itself is also higher. At present, there is no well-developed gas-liquid phase change carbon dioxide energy comprehensive utilization system specifically developed for the data center.

### Technical Problems

Therefore, to address the problem of higher power and heat dissipation demands of the data center in the relate art, the disclosure provides a gas-liquid phase change carbon dioxide energy comprehensive utilization system adapted for a data center and a control method therefor, which can realize the comprehensive utilization of energy, reduce investment and operation cost of the system, meet a heating demand of an evaporator and heat dissipation demand of the data center at the same time, and can cope with various operation conditions.

### SUMMARY

An embodiment of the disclosure provides a gas-liquid phase change carbon dioxide energy comprehensive utilization system adapted for a data center. The gas-liquid phase change carbon dioxide energy comprehensive utilization system adapted for the data center includes an energy storage subsystem, the data center, and a heat balance component. The energy storage subsystem includes a gaseous carbon dioxide management unit, an energy storage component, a liquid storage unit, and an energy release component, which are sequentially connected in that order to form a closed loop. The energy storage component includes a condenser, and the energy storage component is configured to: compress gaseous carbon dioxide output from the gaseous carbon dioxide management unit to obtain compressed gaseous carbon dioxide, and condense the compressed gaseous carbon dioxide by the condenser into liquid carbon dioxide for storing in the liquid storage unit. The energy release component includes an evaporator, and the energy release component is configured to: evaporate, by the evaporator, the liquid carbon dioxide output from the liquid storage unit into gaseous carbon dioxide, expand the gaseous carbon dioxide to perform work, and store the gaseous carbon dioxide after expanding and performing work in the gaseous carbon dioxide management unit. A heat exchange medium inlet of the data center is connected to a heat exchange medium outlet of the evaporator, and a heat exchange medium outlet of the data center is connected to a heat exchange medium inlet of the evaporator. The heat balance component includes a high-temperature transmission pipeline and a low-temperature transmission pipeline. The high-temperature transmission pipeline is connected between the heat exchange medium outlet of the data center and the heat exchange medium inlet of the evaporator, and the low-temperature transmission pipeline is connected between the heat exchange medium inlet of the data center and the heat exchange medium outlet of the evaporator. The heat balance component is configured to: when the gas-liquid phase change carbon dioxide energy comprehensive utilization system adapted for the data center is in an operation condition and heat dissipation of the data center is inconsistent with heat supply required by the evaporator, supplement a high-temperature heat exchange medium to the heat exchange medium inlet of the evaporator through the high-temperature transmission pipeline or supplement a low-temperature heat exchange medium to the heat exchange medium inlet of the data center through the low-temperature transmission pipeline.

In some embodiments, the operation condition includes a first operation condition; and under the first operation condition, the heat dissipation of the data center is less than the heat supply required by the evaporator. The heat balance component includes a heat pump unit; the heat exchange medium inlet of the evaporator is connected to the heat pump unit through the high-temperature transmission pipeline; the heat exchange medium outlet of the evaporator is connected to the heat pump unit through the low-temperature transmission pipeline; and under the first operation condition, a heat exchange medium output from the evaporator to the low-temperature transmission pipeline is heated by the heat pump unit, and then passes through the high-temperature transmission pipeline and finally flows into the evaporator together with a heat exchange medium output from the data center.

In some embodiment, the heat balance component further includes a heat exchange medium storage component, and the heat exchange medium storage component includes a high-temperature medium storage unit disposed on the high-temperature transmission pipeline and a low-temperature medium storage unit disposed on the low-temperature transmission pipeline.

In some embodiments, a heat exchange medium inlet of the condenser is connected to a cold-side outlet of the heat pump unit, and a heat exchange medium outlet of the condenser is connected to a cold-side inlet of the heat pump unit.

In some embodiments, the gas-liquid phase change carbon dioxide energy comprehensive utilization system adapted for the data center has an energy storage subsystem shutdown condition; the gas-liquid phase change carbon dioxide energy comprehensive utilization system adapted for the data center further includes a data center heat exchanger; the data center heat exchanger is connected between the heat exchange medium outlet of the data center and the heat exchange medium inlet of the data center; the data center heat exchanger is connected to the heat pump unit; and the data center heat exchanger is configured to: under the energy storage subsystem shutdown condition, cool the heat exchange medium output from the data center by using a cold energy provided by the heat pump unit.

In some embodiments, the gas-liquid phase change carbon dioxide energy comprehensive utilization system adapted for the data center has an energy storage subsystem shutdown condition; the gas-liquid phase change carbon dioxide energy comprehensive utilization system adapted for the data center further includes a data center heat exchanger and a first water chiller; the data center heat exchanger is connected between the heat exchange medium outlet of the data center and the heat exchange medium inlet of the data center; the first water chiller is connected to the data center heat exchanger and the condenser; the data center heat exchanger is configured to: under the energy storage subsystem shutdown condition, cool the heat exchange medium output from the data center by using a cold energy provided by the first water chiller; and the condenser is configured to: under the operation condition and in an energy storage stage, condense the compressed gaseous carbon dioxide by using the cold energy provided by the first water chiller.

In some embodiments, the operation condition includes a second operation condition; and under the second operation condition, the heat dissipation of the data center is greater than the heat supply required by the evaporator. The heat balance component includes a cooling component; the heat exchange medium outlet of the data center is connected to the cooling component through the high-temperature transmission pipeline; the heat exchange medium inlet of the data center is connected to the cooling component through the low-temperature transmission pipeline; and under the second operation condition, a heat exchange medium output from the data center to the high-temperature transmission pipeline is cooled by the cooling component, and then passes through the low-temperature transmission pipeline and finally flows into the data center together with a heat exchange medium output from the evaporator.

In some embodiment, the cooling component includes a first cooling tower, a first heat exchanger, a second water chiller, and a second cooling tower; the first heat exchanger is connected between the first cooling tower and the low-temperature transmission pipeline; the second water chiller is connected to the first heat exchanger and the second cooling tower; the second water chiller is configured to provide a cold energy for the first heat exchanger; and the second cooling tower is configured to dissipate heat for the second water chiller.

In some embodiment, the gas-liquid phase change carbon dioxide energy comprehensive utilization system adapted for the data center has an energy storage subsystem shutdown condition; the gas-liquid phase change carbon dioxide energy comprehensive utilization system adapted for the data center further includes a data center heat exchanger and a first water chiller; the data center heat exchanger is connected between the heat exchange medium outlet of the data center and the heat exchange medium inlet of the data center; the first water chiller is connected to the data center heat exchanger and the condenser; under the energy storage subsystem shutdown condition, the heat exchange medium output from the data center is divided into two paths, one of the two paths enters the cooling component and is cooled down with a cold energy provided by the second water chiller, the other path of the two paths enters the data center heat exchanger and is cooled down with a cold energy provided by the first water chiller; and the condenser is configured to: under the operation condition and in an energy storage stage, condense the compressed gaseous carbon dioxide by using the cold energy provided by the first water chiller.

In some embodiments, the gas-liquid phase change carbon dioxide energy comprehensive utilization system adapted for the data center further includes a branch pipeline, where the energy storage component includes a compression energy storage part; the compression energy storage part is connected between the gaseous carbon dioxide management unit and the condenser; the energy release component includes an expansion energy release part; the expansion energy release part is connected between the evaporator and the gaseous carbon dioxide management unit; an inlet end of the branch pipeline is connected to an outlet of a compressor of the compression energy storage part; an outlet end of the branch pipeline is connected to an inlet of an expander of the expansion energy release part; and a working fluid flow regulating valve is disposed on the branch pipeline.

In some embodiments, the compression energy storage part includes multi-stage compressors, and the inlet end of the branch pipeline is connected to an outlet of a last-stage compressor of the multi-stage compressors.

An embodiment of the disclosure provides a control method, applied to the gas-liquid phase change carbon dioxide energy comprehensive utilization system adapted for the data center mentioned above. The gas-liquid phase change carbon dioxide energy comprehensive utilization system adapted for the data center includes the operation condition, and the control method includes: under the operation condition and when the heat dissipation of the data center is inconsistent with the heat supply required by the evaporator, supplementing, by the heat balance component, the high-temperature heat exchange medium to the heat exchange medium inlet of the evaporator through the high-temperature transmission pipeline, or supplementing, by the heat balance component, the low-temperature heat exchange medium to the heat exchange medium inlet of the data center through the low-temperature transmission pipeline.

In some embodiments, the gas-liquid phase change carbon dioxide energy comprehensive utilization system adapted for the data center has an energy storage subsystem shutdown condition; the gas-liquid phase change carbon dioxide energy comprehensive utilization system adapted for the data center further includes a data center heat exchanger and a first water chiller; and the control method includes: under the operation condition and in an energy storage stage, condensing, by the condenser, the compressed gaseous carbon dioxide by using the cold energy provided by the first water chiller; and under the energy storage subsystem shutdown condition, cooling, by the data center heat exchanger, a heat exchange medium output from the data center by using a cold energy provided by the first water chiller.

In some embodiments, the gas-liquid phase change carbon dioxide energy comprehensive utilization system adapted for the data center includes a branch pipeline; the energy storage component further includes a compression energy storage part; the compression energy storage part is connected between the gaseous carbon dioxide management unit and the condenser; the energy release component includes an expansion energy release part; the expansion energy release part is connected between the evaporator and the gaseous carbon dioxide management unit; an inlet end of the branch pipeline is connected to an outlet of a compressor of the compression energy storage part; an outlet end of the branch pipeline is connected to an inlet of an expander of the expansion energy release part; and a working fluid flow regulating valve is disposed on the branch pipeline. The control method includes: under the operation condition and in an energy storage stage, opening the working fluid flow regulating valve to make a part of carbon dioxide output by the compressor of the compression energy storage part enter the condenser for condensation, and inputting the remaining part of the carbon dioxide output by the compressor of the compression energy storage part through the branch pipeline to an inlet of the expander of the expansion energy release part for expanding to perform work.

In some embodiments, the control method further includes: in the energy storage stage, adjusting the working fluid flow regulating valve to make a mass flow of carbon dioxide passing through the branch pipeline satisfies a relationship as follows:

$$m = \frac{W}{Δ H}$$

where m represents the mass flow of the carbon dioxide passing through the branch pipeline, W represents a power generation of the expander of the expansion energy release part, and ΔH represents an enthalpy difference between the inlet of the expander and an outlet of the expander.

### Beneficial Effects

As can be seen from the above, the above embodiments of the disclosure can achieve one or more of the following beneficial effects: by coupling the evaporator in the energy storage subsystem with the data center, the evaporator can be supplied with heat and the data center can be cooled simultaneously through the circulating flow of the heat exchange medium between the data center and the evaporator, so that the investment cost of the construction of heating facilities of the evaporator and cooling facilities of the data center can be reduced, and the full utilization of energy can be realized. The configuration of the heat balance component can ensure the stable operation of the energy comprehensive utilization system in a scenario where the heat supply required by the evaporator is inconsistent with the heat dissipation of the data center.

### BRIEF DESCRIPTION OF DRAWINGS

Specific embodiments of the disclosure will be described in detail with reference to accompanying drawings.

FIG. 1 illustrates an overall schematic structural diagram of a gas-liquid phase change carbon dioxide energy comprehensive utilization system adapted for a data center according to embodiments of the disclosure.

FIG. 2 illustrates a schematic structural diagram of an energy storage subsystem in a specific embodiment of the gas-liquid phase change carbon dioxide energy comprehensive utilization system adapted for the data center shown in FIG. 1.

FIG. 3 illustrates a schematic structural diagram corresponding to a specific embodiment of the gas-liquid phase change carbon dioxide energy comprehensive utilization system adapted for the data center shown in FIG. 1.

FIG. 4 illustrates a schematic structural diagram corresponding to another specific embodiment of the gas-liquid phase change carbon dioxide energy comprehensive utilization system adapted for the data center shown in FIG. 1.

FIG. 5 illustrates a schematic structural diagram of an energy storage subsystem in another specific embodiment of the gas-liquid phase change carbon dioxide energy comprehensive utilization system adapted for the data center shown in FIG. 1.

### DESCRIPTION OF REFERENCE NUMERALS

10. Energy storage subsystem; 11. Gaseous carbon dioxide management unit; 12. Energy storage component; 121. Compression energy storage part; 1211. Compressor; 1212. First heat storage unit; 123. Condenser; 1231. working fluid inlet of the condenser 123; 1232. working fluid outlet of the condenser 123; 1233. Heat exchange medium inlet of the condenser 123; 1234. Heat exchange medium outlet of the condenser 123; 13. Liquid storage unit; 14. Energy release components; 141. Evaporator; 1411. Heat exchange medium inlet of the evaporator 141; 1412.
20. Heat exchange medium outlet of the evaporator 141; 1413. working fluid inlet of the evaporator 141; 1414. working fluid outlet of the evaporator 141; 143. Expansion energy release part; 1431. Second heat storage unit; 1432. Expander;
20. Data center; 201. Heat exchange medium inlet of the data center 20; 202. Heat exchange medium outlet of the data center 20; 21. Cabinet;
30. Heat balance component; 31. High-temperature transmission pipeline; 32. Low-temperature transmission pipeline; 33. Heat pump unit; 331. Hot-side inlet of the heat pump unit 33; 332. Hot-side outlet of the heat pump unit 33; 333. Cold-side inlet of the heat pump unit 33; 334. Cold-side outlet of the heat pump unit 33; 34. Heat exchange medium storage component; 341. High-temperature medium storage unit; 342. Low-temperature medium storage unit; 35. Cooling component; 351. First cooling tower; 352. First heat exchanger; 3521. First medium inlet of the first heat exchanger 352; 3522. First medium outlet of the first heat exchanger 352; 3523. Second medium inlet of the first heat exchanger 352; 3524. Second medium outlet of the first heat exchanger 352; 353. Second water chiller; 3531. Cold-side inlet of the second water chiller 353; 3532. Cold-side outlet of the second water chiller 353; 3533. Hot-side inlet of the second water chiller 353; 3534. Hot-side outlet of the second water chiller 353; 354. Second cooling tower;
41. First water chiller; 411. Cold-side inlet of the first water chiller 41; 412. Cold-side outlet of the first water chiller 41; 413. Hot-side inlet of the first water chiller 41; 414. Hot-side outlet of the first water chiller 41; 42. Third cooling tower;
50. Data center heat exchanger; 501. First medium inlet of the data center heat exchanger 50; 502. First medium outlet of the data center heat exchanger 50; 503. Second medium inlet of the data center heat exchanger 50; 504. Second medium outlet of the data center heat exchanger 50;
61. Branch pipeline; 62. Working fluid flow regulating valve;
70. Water supply device;
81. First valve; 82. Second valve; 83. Third valve; 84. Fourth valve; 85. Fifth valve; 86. Sixth valve; 87. Seventh valve; 88. Eighth valve; 89. Ninth valve;
91. First pump; 92. Second pump; 93. Third pump; 94. Fourth pump; 95. Fifth pump; 96. Sixth pump; 97. Seventh pump.

### DETAILED DESCRIPTION OF EMBODIMENTS

In order to make the above-mentioned objectives, features and advantages of the disclosure more clearly and easy to understand, the specific embodiments of the disclosure will be described in detail with accompanying drawings.

In order to better understand the technical solutions of the disclosure, the technical solutions in the embodiments of the disclosure will be described clearly and completely with the accompanying drawings. Apparently, the described embodiments are merely part of the disclosure, not the whole embodiments. Based on the described embodiments in the disclosure, all other embodiments obtained by ordinary technicians in this field without creative work should belong to the scope of protection of the disclosure.

It should be noted that the terms “first” and “second” in the description and claims of the disclosure and the above drawings are used to distinguish similar objects, and are not necessarily used to describe a specific order or sequence. It should be understood that, the terms used in this manner are interchangeable where appropriate, so that the embodiments of the disclosure described herein can be implemented in other orders than those illustrated or described herein. Furthermore, the terms “including” and “having” and any variations thereof are intended to cover non-exclusive inclusion, for example, a process, a method, a system, a product or equipment that includes a series of steps or units is not necessarily limited to those explicitly listed, but may include other steps or units not explicitly listed or inherent to this process, method, product or equipment.

It should also be noted that the division of multiple embodiments in the disclosure is only for the convenience of description, and should not constitute a special limitation. Features in various embodiments can be combined and referenced to each other where they do not conflict.

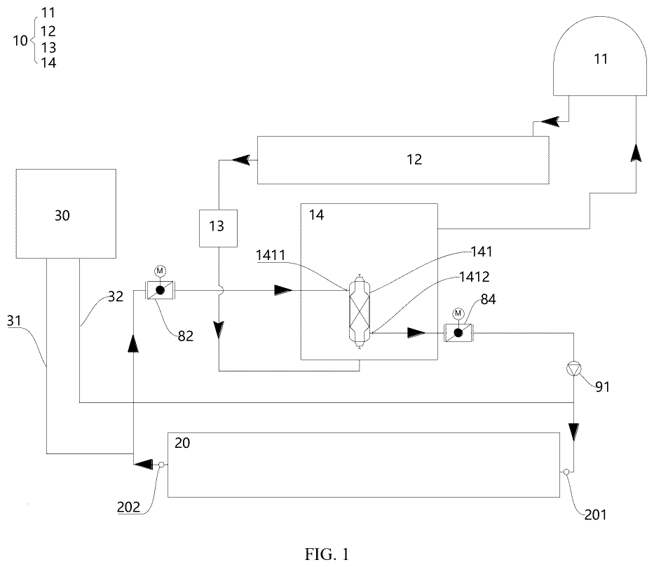

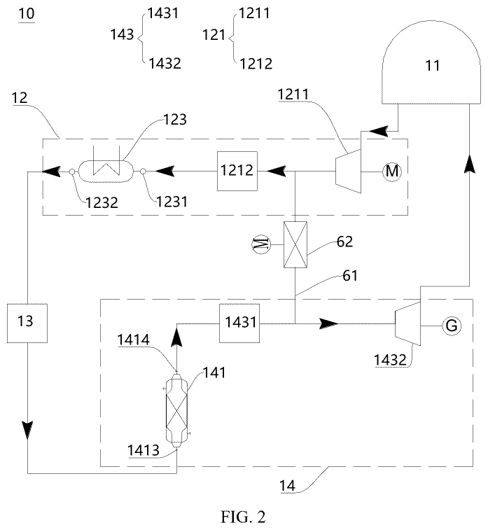

As illustrated in FIG. 1, an embodiment of the disclosure provides a gas-liquid phase change carbon dioxide energy comprehensive utilization system adapted for a data center (referred to as an energy comprehensive utilization system for short), which includes an energy storage subsystem 10, the data center 20, and a heat balance component 30. As illustrated in FIG. 2, the energy storage subsystem 10 includes a gaseous carbon dioxide management unit 11, an energy storage component 12, a liquid storage unit 13, and an energy release component 14, which are sequentially connected in that order to form a closed loop. The energy storage component 12 includes a condenser 123. The energy storage component 12 is configured to: compress gaseous carbon dioxide output from the gaseous carbon dioxide management unit 11 to obtain compressed gaseous carbon dioxide, condense the compressed gaseous carbon dioxide by the condenser 123 into liquid carbon dioxide, and store the liquid carbon dioxide in the liquid storage unit 13. The energy release component 14 includes an evaporator 141. The energy release component 14 is configured to: evaporate, by the evaporator 141, the liquid carbon dioxide output from the liquid storage unit 13 into gaseous carbon dioxide, expand the gaseous carbon dioxide to perform work, and store the gaseous carbon dioxide after expanding and performing work in the gaseous carbon dioxide management unit 11.

A heat exchange medium inlet 201 of the data center 20 is connected to a heat exchange medium outlet 1412 of the evaporator 141, and a heat exchange medium outlet 202 of the data center 20 is connected to a heat exchange medium inlet 1411 of the evaporator 141.

The heat balance component 30 includes a high-temperature transmission pipeline 31 and a low-temperature transmission pipeline 32. The high-temperature transmission pipeline 31 is connected between the heat exchange medium outlet 202 of the data center 20 and the heat exchange medium inlet 1411 of the evaporator 141, and the low-temperature transmission pipeline 32 is connected between the heat exchange medium inlet 201 of the data center 20 and the heat exchange medium outlet 1412 of the evaporator 141.

Specifically, the heat balance component 30 is configured to: when the gas-liquid phase change carbon dioxide energy comprehensive utilization system adapted for the data center is in an operation condition and heat dissipation of the data center 20 is inconsistent with heat supply required by the evaporator 141, supplement a high-temperature heat exchange medium to the heat exchange medium inlet 1411 of the evaporator 141 through the high-temperature transmission pipeline 31 or supplement a low-temperature heat exchange medium to the heat exchange medium inlet 201 of the data center 20 through the low-temperature transmission pipeline 32.

An embodiment of the disclosure provides a control method, applied to the gas-liquid phase change carbon dioxide energy comprehensive utilization system adapted for the data center mentioned above. The control method includes: under the operation condition and when the heat dissipation of the data center 20 is inconsistent with the heat supply required by the evaporator 141, supplementing, by the heat balance component 30, the high-temperature heat exchange medium to the heat exchange medium inlet 1411 of the evaporator 141 through the high-temperature transmission pipeline 31, or supplementing, by the heat balance component 30, the low-temperature heat exchange medium to the heat exchange medium inlet 201 of the data center 20 through the low-temperature transmission pipeline 32.

Specifically, the energy storage subsystem 10 is a gas-liquid phase change carbon dioxide energy storage system. The gas-liquid phase change carbon dioxide energy storage system uses carbon dioxide as a working fluid and includes an energy storage phase and an energy release phase. In the energy storage phase, gaseous carbon dioxide at normal temperature and pressure is compressed into high-temperature and high-pressure gaseous carbon dioxide and then the high-temperature and high-pressure gaseous carbon dioxide undergoes heat exchange. Heat generated from heat the exchange is stored. The high-temperature and high-pressure gaseous carbon dioxide is converted into low-temperature and high-pressure gaseous carbon dioxide, and the low-temperature and high-pressure gaseous carbon dioxide is then condensed into low-temperature and high-pressure liquid carbon dioxide. Energy is stored in the form of a compression energy with the liquid carbon dioxide. In the energy storage phase, the energy is stored in the form of both thermal energy and compression energy. In the energy release phase, the low-temperature and high-pressure liquid carbon dioxide is heated and converted into low-temperature and high-pressure gaseous carbon dioxide. The low-temperature and high-pressure gaseous carbon dioxide absorbs the stored heat and becomes high-temperature and high-pressure gaseous carbon dioxide, and then expands to perform work and generate electricity, finally converting into gaseous carbon dioxide at normal temperature and pressure. According to the above gas-liquid phase change process, the energy storage subsystem 10 can, for example, enter the energy storage phase during off-peak electricity hours to store energy and enter the energy release phase during peak electricity hours or other times when electricity is needed to generate power for users. The terms “high-temperature” and “low-temperature” are relative, and mean that the high-temperature is higher than the low-temperature. Similarly, “high-pressure” and “low-pressure” are relative, and mean that the high-pressure is higher than the low-pressure.

The gaseous carbon dioxide management unit 11 can also be called a gas chamber or a gas storage, which is used to store gaseous carbon dioxide. In some possible implementations, the gaseous carbon dioxide management unit 11 adopts an air-supported membrane structure, whose volume can change. When the gaseous carbon dioxide is charged in the air-supported membrane structure, the volume of the air-supported membrane structure increases, and when the gaseous carbon dioxide flows out from the air-supported membrane structure, the volume of the air-supported membrane structure decreases, thereby maintaining a constant pressure inside the gaseous carbon dioxide management unit 11. This air-supported membrane structure can be a double-layer membrane structure, including a ground membrane, an inner membrane, and an outer membrane. The outer membrane is used to resist wind and snow. There is a sandwich cavity between the inner and outer membranes, and gas inside the sandwich cavity supports the outer membrane upward to maintain a shape of the air-supported membrane structure and prevent the air-supported membrane structure from collapsing. The inner membrane and the ground membrane together define an accommodating cavity for storing the gaseous carbon dioxide. A pressure and a temperature inside the accommodating cavity can be maintained within a certain range to meet the energy storage requirements. For example, the pressure of the gaseous carbon dioxide inside the gaseous carbon dioxide management unit 11 can be close to an ambient pressure, i.e., a surrounding atmospheric pressure. In some embodiments, a temperature inside the gaseous carbon dioxide management unit 11 is within a range of −40° C. to 70° C. For example, the temperature can be −40° C., 0° C., 15° C., 20° C., 25° C., 30° C., 35° C., 40° C., 50° C., 60° C., or 70° C. A pressure difference between a atmospheric pressure inside the gaseous carbon dioxide management unit 11 and an external atmospheric pressure is less than 1000 Pa.

Specifically, in addition to the condenser 123, the energy storage component 12 further includes a compression energy storage part 121, which is connected between the gaseous carbon dioxide management unit 11 and the condenser 123. More specifically, the compression energy storage part 121 includes a compressor 1211 and a first heat storage unit 1212. The compressor 1211 is used to compress the gaseous carbon dioxide, and the first heat storage unit 1212 is used to exchange heat with the compressed gaseous carbon dioxide to store the heat.

Specifically, a main shaft of the compressor 1211 is connected to an electric motor. The electric motor connected to the compressor 1211 may be connected to a municipal power grid, and during off-peak electricity hours, the compressor 1211 is driven by a municipal power supply. Alternatively, the electric motor connected to the compressor 1211 may be connected to a power output end of a green energy power generation system, such as a solar power generation system or a wind power generation system, to drive the compressor 1211 with electricity generated by the green energy power generation system. The compressor 1211 can be multi-stage compressors connected in series. An outlet of each stage of the compressor 1211 is connected to a first heat storage unit 1212. The first heat storage unit 1212 may be a heat exchanger, specifically, may be a double-pipe heat exchanger, such as a plate heat exchanger or a tube heat exchanger. The first heat storage unit 1212 can use heat exchange media such as water, thermal oil, or molten salt to exchange heat with the compressed gaseous carbon dioxide to absorb and store heat. The condenser 123 can be a shell-and-tube condenser or a double-pipe condenser.

The liquid storage unit 13 can be a stainless-steel tank, and is used to store the low-temperature and high-pressure liquid carbon dioxide condensed by the condenser 123. Of course, the carbon dioxide in the liquid storage unit 13 may also exist in a gas-liquid mixture form. For example, a pressure of the liquid carbon dioxide in the liquid storage unit 13 is in a range of 2 MPa and 10 MPa. For example, pressure of the liquid carbon dioxide in the liquid storage unit 13 may be 2 MPa, 5 MPa, 6 MPa, 7 MPa, 7.2 MPa, 7.5 MPa, 8 MPa, or 10 MPa.

In an embodiment, a temperature of the liquid carbon dioxide in the liquid storage unit 13 may be no higher than 50° C., especially no higher than 30° C., for example, between 20° C. and 30° C. For example, when the liquid carbon dioxide flows into the liquid storage unit 13, the temperature of the liquid carbon dioxide is between 20° C. and 30° C. to ensure that the temperature of the liquid carbon dioxide in the liquid storage unit 13 does not exceed 30° C.

For example, the temperature of the liquid carbon dioxide in the liquid storage unit 13 is between 20° C. and 30° C., and the pressure of the liquid carbon dioxide in the liquid storage unit 13 is between 7 MPa and 7.5 MPa. As such, potential safety hazards caused by increases in temperature and pressure of the liquid carbon dioxide in the liquid storage unit 13 can be avoided. This makes the energy storage subsystem 10 more suitable for deployment in densely populated areas such as residential areas, schools, hospitals, stations, and commercial centers.

The working fluid inlet 1413 of the evaporator 141 is connected to the liquid storage unit 13. In addition to the evaporator 141, the power release component 14 further includes an expansion energy release part 143, and the expansion energy release part 143 is connected between the evaporator 141 and the gaseous carbon dioxide management unit 11. Specifically, the expansion energy release part 143 includes a second heat storage unit 1431 and an expander 1432. The second heat storage unit 1431 is connected to a working fluid outlet 1414 of the evaporator 141. The second heat storage unit 1431 can be configured as a plate heat exchanger, a tube heat exchanger, or another type of heat exchanger, like the first heat storage unit 1212. The second heat storage unit 1431 can use the same heat exchange medium as the first heat storage unit 1212 to exchange heat with the evaporated gaseous carbon dioxide to increase the temperature of the evaporated gaseous carbon dioxide. Heat exchange medium sides of the second heat storage unit 1431 and the first heat storage unit 1212 can be connected in a closed loop and provided with corresponding heat exchange medium storage tanks, which allows the heat exchange medium to absorb heat and store the heat in the first heat storage unit 1212 during the energy storage phase and the heat absorbed by the first heat storage unit 1212 is used to increase the temperature of the carbon dioxide by the second heat storage unit 1431 during the energy release phase. A main shaft of the expander 1432 is connected to a generator. The heated gaseous carbon dioxide enters the expander 1432 to expand and perform work, to thereby drive the generator to produce electricity. After the work is done, the gaseous carbon dioxide enters the gaseous carbon dioxide management unit 11 for storage. The generator connected to the expander 1432 is connected to a user to supply power to the user. In embodiments of the disclosure, the user is the data center 20, and the generator connected to the expander 1432 is connected to a power input end of the data center 20 to supply power for the data center 20.

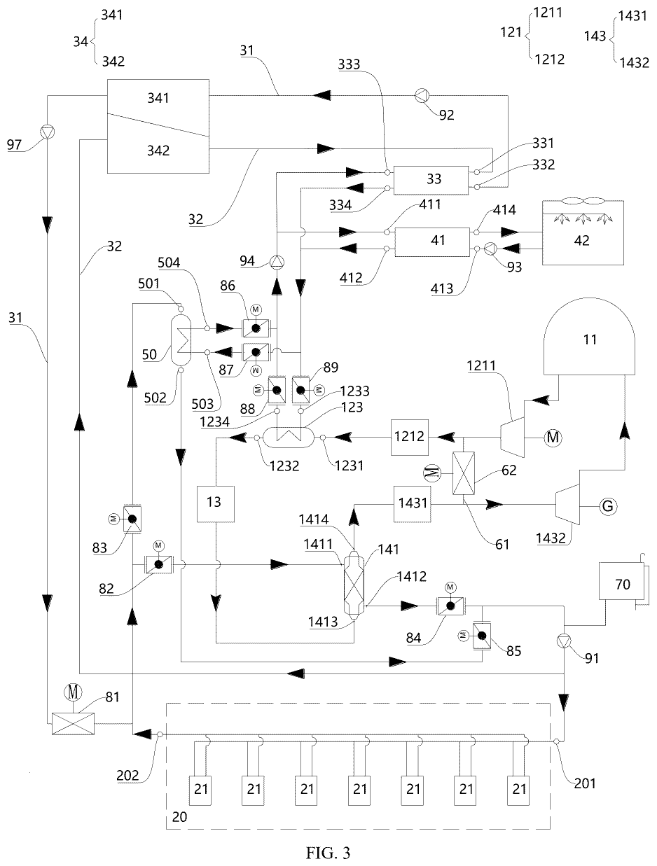

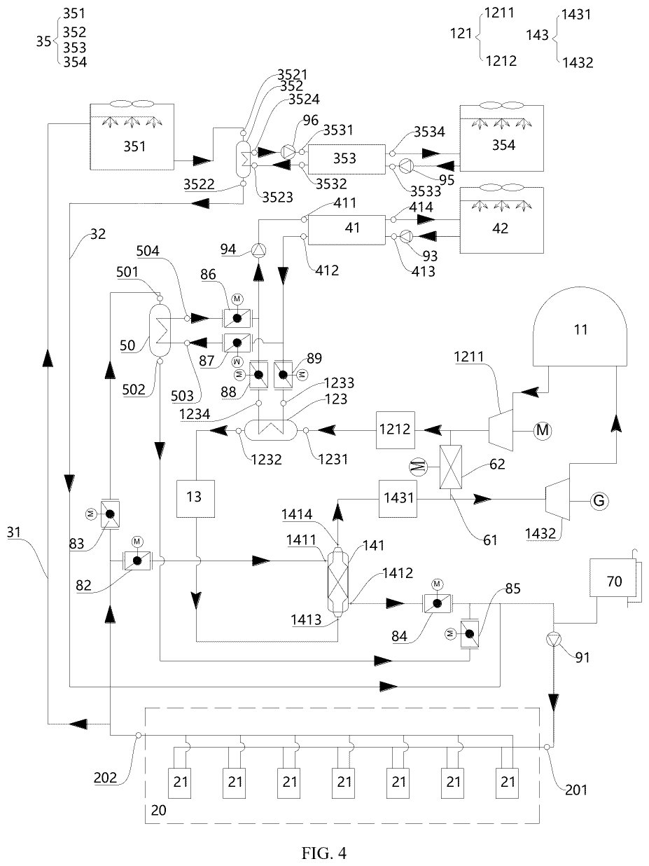

The data center 20 is a facility used for the centralized processing, storage, transmission, exchange, and management of data information. The data center 20 may include a server, a storage device, a switch, or other devices. The power input end of the data center 20 may be connected to the generator connected to the expander 1432, with a power generated by the energy storage subsystem 10 serving as a main power source for the data center 20. The power input end of the data center 20 may be further connected to the municipal power grid, and municipal electricity is used as a backup power source to ensure a power demand of the data center 20 during a shutdown period of the energy storage subsystem 10. The data center 20 includes multiple racks 21 (referring to FIG. 3 or FIG. 4), each of the multiple racks 21 generates a significant amount of heat during operation and has a high heat dissipation demand. In this embodiment, the heat exchange medium inlet 201 of the data center 20 is connected to the heat exchange medium outlet 1412 of the evaporator 141, and the heat exchange medium outlet 202 of the data center 20 is connected to the heat exchange medium inlet 1411 of the evaporator 141, therefore, the heat exchange medium can circulate between the data center 20 and the evaporator 141. Specifically, the heat exchange medium output by the evaporator 141 is delivered to the data center 20 by the first pump 91, so that the heat exchange medium absorbs the heat generated by the data center 20 when it flows through the data center 20, and then enters the evaporator 141 to provide heat for carbon dioxide flowing through the evaporator 141 to evaporate liquid carbon dioxide into gaseous carbon dioxide. After providing heat to the carbon dioxide and cooling down, the heat exchange medium is reintroduced into the data center 20 to absorb the heat emitted by the data center 20 again. This cycle not only provides heat to the evaporator 141 but also cools the data center 20. In a traditional carbon dioxide energy storage system, a heat source device is required for the evaporator 141 to achieve the evaporation of carbon dioxide, and a traditional data center needs a cooling source device to dissipate heat. Therefore, the configuration described in the above embodiments of the disclosure achieves full utilization of energy and reduces the investment and operating costs of the heat source device and supporting pipeline facilities for the evaporator 141, as well as the cooling source device and supporting pipeline facilities for the data center 20.

The operation condition of the energy comprehensive utilization system provided in the embodiments of the disclosure includes an operation condition of the data center 20 and an operation condition the energy storage subsystem 10. The operation condition of the energy storage subsystem 10 includes an energy storage phase and an energy release phase. The data center 20 operates 24 hours a day, and the energy storage subsystem 10 also operates 24 hours a day during the energy release phase of the energy storage subsystem 10. A duration of the energy storage phase can be specifically set according to peak and off-peak electricity price policies and a duration of power generation from green energy power generation systems such as wind and solar power in a location of the energy comprehensive utilization system. Setting a duration of the energy release phase of the energy storage subsystem 10 to be consistent with an operation duration of the data center 20 can ensure that the evaporator 141 and the data center 20 maintain mutual circulating heat exchange under the operation condition of the energy comprehensive utilization system. This ensures the full utilization of energy and ensures the continuous heat dissipation and stable power supply of the data center 20.

In the heat balance component 30, the high-temperature transmission pipeline 31 and the low-temperature transmission pipeline 32 are relative, which means that a temperature of a heat transfer medium flowing through the high-temperature transmission pipeline 31 is higher than a temperature of a heat transfer medium flowing through the low-temperature transmission pipeline 32. An operation principle of the energy comprehensive utilization system provided by the embodiment of the disclosure and a principle of the control method are as follows: considering that the heat dissipation of the data center 20 may not match the heat supply required by the evaporator 141, for example, the heat supply required by the evaporator 141 may be greater than the heat dissipation of the data center 20, under the operation condition of the energy comprehensive utilization system, the heat balance component 30 supplements a high-temperature heat exchange medium to the heat exchange medium inlet 1411 of the evaporator 141 through the high-temperature transmission pipeline 31 to ensure the heat supply of the evaporator 141. Alternatively, the heat dissipation of the data center 20 may exceed the heat supply required by the evaporator 141, under the operation condition of the energy comprehensive utilization system, the heat balance component 30 supplements a low-temperature heat exchange medium to the heat exchange medium inlet 201 of the data center 20 through the low-temperature transmission pipeline 32 operation condition, to ensure the normal heat dissipation of the data center 20. The high-temperature heat exchange medium and the low-temperature heat exchange medium herein are relative, which means that the high-temperature heat exchange medium has a higher temperature than the low-temperature heat exchange medium. Because the heat balance component 30 only needs to supplement a heat difference between the data center 20 and the evaporator 141, which is far less than a total heat dissipation of the data center 20 and a total required heat supply of the evaporator 141, although the heat balance component 30 is added in this embodiment, compared with the cold source device of the traditional data center and the heat source device of the traditional evaporator, the investment and operation cost are still greatly reduced.

Specifically, the operation condition of the energy comprehensive utilization system can be divided into a first operation condition and a second operation condition, and the heat balance component 30 and corresponding facilities and pipelines are set for the first operation condition and the second operation condition. Under the first operation condition, the heat dissipation of the data center 20 is less than the heat supply required by the evaporator 141. A structure of the energy comprehensive utilization system shown in FIG. 3 can be adapted to the first operation condition. The heat balance component 30 includes a heat pump unit 33. The heat exchange medium inlet 1411 of the evaporator 141 is connected to the heat pump unit 33 through the high-temperature transmission pipeline 31. The heat exchange medium outlet 1412 of the evaporator 141 is connected to the heat pump unit 33 through the low-temperature transmission pipeline 32. Under the first operation condition, a heat exchange medium output from the evaporator 141 to the low-temperature transmission pipeline 32 is heated by the heat pump unit 33, and then passes through the high-temperature transmission pipeline 31 and finally flows into the evaporator 141 together with a heat exchange medium output from the data center 20.

Specifically, the heat pump unit 33 is a device capable of transferring heat from a low-grade heat source to a high-grade heat source. A working principle of the heat pump unit 33 is based on the inverse Carnot cycle to realize heat transfer through a phase change of refrigerant in the energy comprehensive utilization system. Specifically, a hot-side inlet 331 and a hot-side outlet 332 of the heat pump unit 33 correspond to an inlet and an outlet of the high-grade heat source respectively. An input end of the high-temperature transmission pipeline 31 is connected to the hot-side outlet 332 of the heat pump unit 33, and an output end of the high-temperature transmission pipeline 31 is connected to the heat exchange medium inlet 1411 of the evaporator 141 (which can be connected on a connecting pipeline between the heat exchange medium inlet 1411 of the evaporator 141 and the heat exchange medium outlet 202 of the data center 20). An input end of the low-temperature transmission pipeline 32 is connected to the heat exchange medium outlet 1412 of the evaporator 141 (which can be connected on a connecting pipeline between the heat exchange medium outlet 1412 of the evaporator 141 and the heat exchange medium inlet 201 of the data center 20), and an output end of the low-temperature transmission pipeline 32 is connected to the hot-side inlet 331 of the heat pump unit 33.

In this way, the control method for the energy comprehensive utilization system may include: under the first operation condition, the heat pump unit 33 receives a part of a heat exchange medium output by the evaporator 141 through the low-temperature transmission pipeline 32, heats the received part of the heat exchange medium, and outputs the heated heat exchange medium to the evaporator 141 through the high-temperature transmission pipeline 31.

Through the above arrangement and the control method, the part of the heat exchange medium can be circularly heated by the heat pump unit 33 to continuously supplement the high-temperature heat exchange medium to the evaporator 141, to ensure that the normal heating demand of the evaporator 141 can be met.

In some embodiments, the heat balance component 30 further includes a heat exchange medium storage component 34. The heat exchange medium storage component 34 includes a high-temperature medium storage unit 341 disposed on the high-temperature transmission pipeline 31 and a low-temperature medium storage unit 342 disposed on the low-temperature transmission pipeline 32. The high-temperature medium storage unit 341 and the low-temperature medium storage unit 342 are containers with storage functions, which may be boxes, tanks and the like. The high-temperature medium storage unit 341 and the low-temperature medium storage unit 342 may be independent containers. For example, the heat exchange medium storage component 34 may adopt a thermocline water tank (also referred to as stratified thermal storage tank). The thermocline water tank can make hot water (i.e. high-temperature heat exchange medium) naturally float on an upper layer, while cold water (i.e. low-temperature heat exchange medium) sinks on a lower layer, forming a temperature transition zone (i.e. thermocline) between the cold water and the hot water. A hot water area in the upper layer of the thermocline water tank forms the high-temperature medium storage unit 341, and a cold water area in the lower layer of the thermocline water tank forms the low-temperature medium storage unit 342.

The heat exchange medium storage component 34 can realize the function of storing both the high-temperature heat exchange medium and the low-temperature heat exchange medium by using the thermocline water tank, which can reduce the number of device and an occupied area, and can quickly respond to a change of cold and heat load, thus improving the flexibility and adaptability of the heat balance component 30.

The high-temperature medium storage unit 341 is used to store a high-temperature heat exchange medium output by the heat pump unit 33, and the low-temperature medium storage unit 342 is used to store the low-temperature heat exchange medium output to the heat pump unit 33 through the low-temperature transmission pipeline 32. By setting the high-temperature medium storage unit 341 and the low-temperature medium storage unit 342, the heat pump unit 33 does not need to start and stop synchronously with the evaporator 141 and the data center 20, and a working time of the heat pump unit 33 can be adjusted according to actual needs. Moreover, the arrangement of the high-temperature medium storage unit 341 and the low-temperature medium storage unit 342 makes it easy to adjust a flow rate and a supplement period of the heat exchange medium supplemented to the evaporator 141 by the heat balance component 30.

In some embodiments, referring to FIG. 3, the high-temperature transmission pipeline 31 is further provided with a seventh pump 97 thereon, and an inlet of the seventh pump 97 is connected to the high-temperature medium storage unit 341. Under the first operation condition, a heat exchange medium stored in the high-temperature medium storage unit 341 may be powered by the seventh pump 97 to transport the heat exchange medium to the evaporator 141 to supplement a high-temperature heat exchange medium for the evaporator 141.

In some embodiments, the high-temperature medium storage unit 341 is provided with a first valve 81 thereon, which is, for example, a flow regulating valve with an adjustable opening. By adjusting an opening of the first valve 81, an amount of heat exchange medium supplemented to the evaporator 141 can be adjusted to match the heat supply required by the evaporator 141 and the heat dissipation of the data center 20. Specifically, a temperature detection device and a flow detection device can be arranged at the heat exchange medium inlet 1411 of the evaporator 141 to detect a temperature and a flow of the heat exchange medium input into the evaporator 141, and the opening of the first valve 81 can be adjusted according to a temperature detection result and the heat supply required by the evaporator 141. For example, if the heat dissipation of the data center 20 is reduced due to a load reduction operation of the data center 20, the opening of the first valve 81 needs to be increased to supplement more high-temperature heat exchange medium. For example, if a full-load and high-power operation of the data center 20 leads to an increase in the heat dissipation of the data center 20, the opening of the first valve 81 needs to be reduced or even closed to ensure that the heat of the heat exchange medium output to the evaporator 141 through the data center 20 and the heat balance component 30 just meets the heat demand of the evaporator 141, so as to ensure the stable operation of the energy comprehensive utilization system.

In some embodiments, a cold-side inlet 333 and a cold-side outlet 334 of the heat pump unit 33 correspond to an inlet and an outlet of a low-grade heat source, respectively. A heat exchange medium inlet 1233 of the condenser 123 is connected to the cold-side outlet 334 of the heat pump unit 33, and a heat exchange medium outlet 1234 of the condenser 123 is connected to the cold-side inlet 333 of the heat pump unit 33. Therefore, the heat pump unit 33 can provide a partial cold source for the condenser 123 when the heat pump unit 33 operates during the energy storage stage. Specifically, gaseous carbon dioxide enters the condenser 123 from a working fluid inlet 1231 of the condenser 123 to exchange heat with the heat exchange medium input from the heat pump unit 33 to the heat exchange medium inlet 1233 of the condenser 123, so that the gaseous carbon dioxide absorbs a cold energy and condenses into liquid carbon dioxide, the liquid carbon dioxide is output to the liquid storage unit 13 from the working medium outlet 1232 of the condenser 123, and the heat exchange medium absorbs the heat of the gaseous carbon dioxide and is heated to obtain a heated heat exchange medium. The heated exchange medium is output from the heat exchange medium outlet 1234 of the condenser 123, and is delivered to the cold-side inlet 333 of the heat pump unit 33 through a fourth pump 94. The heat pump unit 33 uses the heat of the heat exchange medium input from the cold-side inlet 333 of the heat pump unit 33 to realize heating, the hot-side outlet 332 of the heat pump unit 33 outputs the high-temperature heat exchange medium to the high-temperature transmission pipeline 31 through a second pump 92, and the cooled heat exchange medium is output through the cold-side outlet 334 of the heat pump unit 33 again to provide a cold energy for the condenser 123.

In this way, the control method for the energy comprehensive utilization system can include: under the first operation condition and in the energy storage stage, condensing, by the condenser 123, carbon dioxide by using the cold energy provided by the heat pump unit 33, and using, by the heat pump unit 33, the heat absorbed from the condenser 123 for heating.

Through the above arrangement, the heat pump unit 33 can provide high-temperature heat exchange medium to the high-temperature medium storage unit 341 while working in the energy storage stage to provide circulating cooling for the condenser 123, so that the full utilization of heat energy and equipment can be realized.

In some embodiments, the comprehensive energy utilization system further has an energy storage subsystem shutdown condition. The energy comprehensive utilization system further includes a data center heat exchanger 50, which is connected between the heat exchange medium outlet 202 and the heat exchange medium inlet 201 of the data center 20, and is connected to the heat pump unit 33. The data center heat exchanger 50 is used to cool the heat exchange medium output from the data center 20 by using the cold energy provided by the heat pump unit 33 under the energy storage subsystem shutdown condition.

Specifically, when equipment failure that occurs in the energy storage subsystem 10 or other reason requires an energy release component 14 to stop working for maintenance, the comprehensive energy utilization system will enter the energy storage subsystem shutdown condition. At this time, the evaporator 141 stops working, and there is no need to provide heat for the evaporator 141, so the evaporator 141 cannot dissipate heat from the data center 20. In this embodiment, the data center heat exchanger 50 is provided. A first medium inlet 501 of the data center heat exchanger 50 is connected to the heat exchange medium outlet 202 of the data center 20, and a first medium outlet 502 of the data center heat exchanger 50 is connected to the heat exchange medium inlet 201 of the data center 20, so that a heat exchange medium can circulate between the data center 20 and the data center heat exchanger 50. A second medium inlet 503 of the data center heat exchanger 50 is connected to the cold-side outlet 334 of the heat pump unit 33, and a second medium outlet 504 of the data center heat exchanger 50 is connected to the cold-side inlet 333 of the heat pump unit 33, so that a heat exchange medium can circulate between the data center heat exchanger 50 and the heat pump unit 33. The heat exchange medium flowing through the data center 20 can exchange heat with the heat exchange medium flowing through the heat pump unit 33 through the data center heat exchanger 50 to dissipate heat from the data center 20 and provide heat for the heat pump unit 33 to produce high-temperature heat exchange medium.

Thus, the control method for the energy comprehensive utilization system can include: under the energy storage subsystem shutdown condition and in the energy storage stage, using, by the data center heat exchanger 50, the cold energy provided by the heat pump unit 33 to dissipate heat from the heat exchange medium output by the data center 20, and using, by the heat pump unit 33, the heat absorbed from the data center heat exchanger 50 to heat.

According to the above arrangement, the heat pump unit 33 can be operated under the energy storage subsystem shutdown condition, the cold energy provided by the heat pump unit 33 can be used to dissipate heat for the data center 20, and the high-temperature heat exchange medium prepared by the heat pump unit 33 can be used to supplement heat to the evaporator 141 under the first operation condition, so that the full utilization of device and heat can be realized, the waste of resources and the investment cost of equipment can be reduced, and a standby cold source is not required for the shutdown condition of the evaporator 141, so that the comprehensive energy utilization system can be adapted.

In some embodiments, the comprehensive energy utilization system includes a data center heat exchanger 50 and a first water chiller 41. The data center heat exchanger 50 is connected between the heat exchange medium outlet 202 and the heat exchange medium inlet 201 of the data center 20. The first water chiller 41 is connected to the data center heat exchanger 50 and the condenser 123. The data center heat exchanger 50 is used to cool the heat exchange medium output from the data center 20 by using the cold energy provided by the first water chiller 41 under the energy storage subsystem shutdown condition. The condenser 123 is used to condense carbon dioxide by using the cold energy provided by the first water chiller 41 under the operation condition and in the energy storage stage.

Specifically, the first water chiller 41 is used to prepare a low-temperature heat exchange medium, which may be a screw water chiller, a scroll water chiller, or a centrifugal water chiller. Specifically, a cold-side inlet 411 of the first water chiller 41 is connected to the second medium outlet 504 of the data center heat exchanger 50 and the heat exchange medium outlet 1234 of the condenser 123, and a cold-side outlet 412 of the first water chiller 41 is connected to the second medium inlet 503 of the data center heat exchanger 50 and the heat exchange medium inlet 1233 of the condenser 123. Corresponding valves, such as a sixth valve 86, a seventh valve 87, an eighth valve 88 and a ninth valve 89 shown in FIG. 3, can be set respectively, and a heat exchange medium output by the first water chiller 41 can be selectively output to the data center heat exchanger 50 or the condenser 123 by controlling open or closed states of the corresponding valves. For example, in the energy storage stage, the sixth valve 86 and the seventh valve 87 are closed, and the eighth valve 88 and the ninth valve 89 are opened, so that the heat exchange medium output by the first water chiller 41 enters the condenser 123 to provide a cold energy. Under the energy storage subsystem shutdown condition, the evaporator 141 stops working and cannot dissipate heat to the data center 20. At this time, the condenser 123 does not work, so the sixth valve 86 and the seventh valve 87 can be opened and the eighth valve 88 and the ninth valve 89 can be closed, so that the heat exchange medium output by the first water chiller 41 enters the data center heat exchanger 50 to provide a cold energy to dissipate heat for the data center 20.

In this way, the control method for the energy comprehensive utilization system can include: under the operation condition and in the energy storage stage, condensing, by the condenser 123, carbon dioxide by using the cold energy provided by the first water chiller 41; and under the energy storage subsystem shutdown condition, using, by the data center heat exchanger 50, the cold energy provided by the first water chiller 41 to cool the heat exchange medium output from the data center 20.

According to the above arrangement and the control method, the cold energy provided by the first water chiller 41 can not only meet the heat dissipation demand under normal operation conditions, but also ensure the heat dissipation demand of the data center 20 under the shutdown conditions of the energy storage subsystem, and there is no need to put another standby cold source into the data center 20, which can reduce the investment cost of equipment. In some embodiments, since the first water chiller 41 can be provided with multiple water chillers, and the backup water chiller is provided for the condenser 123, the sixth valve 86, the seventh valve 87, the eighth valve 88 and the ninth valve 89 can also be opened at the same time when the energy release component 14 is shut down for maintenance but the energy storage component 12 is still in normal operation, and the multiple water chillers of the first water chiller 41 can provide cold energy for the condenser 123 and the data center heat exchanger 50 respectively, which can also reduce the equipment investment cost.

Specifically, for example, a third cooling tower 42 is provided to dissipate heat for the first water chiller 41. An input end of the third cooling tower 42 is connected to a hot-side outlet 414 of the first water chiller 41, and an output end of the third cooling tower 42 is connected to a hot-side inlet 413 of the first water chiller 41 through a third pump 93.

In some embodiments, as shown in FIG. 3, it is possible to couple the heat pump unit 33 with the first water chiller 41. Specifically, the cold-side inlet 333 of the heat pump unit 33 is connected to the cold-side inlet 411 of the first water chiller 41, and the cold-side outlet 334 of the heat pump unit 33 is connected to the cold-side outlet 412 of the first water chiller 41. The first water chiller 41 and the heat pump unit 33 can jointly provide a cold energy for the condenser 123 in the energy storage stage, and the first water chiller 41 and the heat pump unit 33 can jointly provide a cold energy for the data center heat exchanger 50 under the energy storage subsystem shutdown condition. In this way, the control method for the energy comprehensive utilization system can include: under the first operation condition and in the energy storage stage, jointly providing, by the heat pump unit 33 and the first water chiller 41, a cold energy for the condenser 123 to condense carbon dioxide, and using, by the heat pump unit 33, the heat absorbed from the condenser 123 to heat. Under the energy storage subsystem shutdown condition, the heat pump unit 33 and the first water chiller 41 jointly provide a cold energy for the data center heat exchanger 50 to dissipate heat from the data center 20, and the heat pump unit 33 uses the heat absorbed from the data center heat exchanger 50 to heat.

Under the second operation condition, the heat dissipation of the data center 20 is greater than the heat supply required by the evaporator 141. A structure of the energy comprehensive utilization system shown in FIG. 4 can be adapted to the second operation condition. The heat balance component 30 includes a cooling component 35, and the heat exchange medium outlet 202 of the data center 20 is connected to the cooling component 35 through the high-temperature transmission pipeline 31. The heat exchange medium inlet 201 of the data center 20 is also connected to the cooling component 35 through the low-temperature transmission pipeline 32. Under the second operation condition, a heat exchange medium output from the data center 20 to the high-temperature transmission pipeline 31 is cooled by the cooling component 35, and then passes through the low-temperature transmission pipeline 32 and finally flows into the data center 20 together with the heat exchange medium output from the evaporator 141.

The cooling component 35 is used to supplement the cold energy. In some embodiments, when a site where the energy comprehensive utilization system is built is located near a water source such as a river or a lake, water from the water source can be transported to the data center 20 through the low-temperature transmission pipeline 32 by a water pump to cool the data center 20 together with the heat exchange medium output by the evaporator 141, in this case, the water pump can replace the cooling component 35. Specifically, in this embodiment, an input end of the high-temperature transmission pipeline 31 is connected to the heat exchange medium outlet 202 of the data center 20 (which can be connected on a connecting pipeline between the heat exchange medium outlet 202 of the data center 20 and the heat exchange medium inlet 1411 of the evaporator 141), and an output end of the high-temperature transmission pipeline 31 is connected to the cooling component 35. An input end of the low-temperature transmission pipeline 32 is connected to the heat exchange medium inlet 201 of the data center 20 (which can be connected to a pipeline between the heat exchange medium inlet 201 of the data center 20 and the heat exchange medium outlet 1412 of the evaporator 141), and an output end of the low-temperature transmission pipeline 32 is connected to the cooling component 35.

In this way, the control method for the energy comprehensive utilization system can include: under the second operation condition, receiving, by the cooling component 35, a part of the heat exchange medium output by the data center 20 through the high-temperature transmission pipeline 31, cooling the received part of the heated exchange medium, and outputting the cooled heat exchange medium to the data center 20 through the low-temperature transmission pipeline 32.

Through the above arrangement, it is possible to continuously supplement the low-temperature heat exchange medium to the data center 20 by circulating cooling the part of the heat exchange medium through the cooling component 35, thus ensuring to meet the normal heat dissipation demand of the data center 20.

In some specific embodiments, the cooling component 35 includes a first cooling tower 351, a first heat exchanger 352, a second water chiller 353, and a second cooling tower 354. The first heat exchanger 352 is connected between the first cooling tower 351 and the low-temperature transmission pipeline 32. The second water chiller 353 is connected to the first heat exchanger 352 and the second cooling tower 354. The second water chiller 353 is used to provide a cold energy for the first heat exchanger 352, and the second cooling tower 354 is used to dissipate heat for the second water chiller 353.

The first cooling tower 351 and the second cooling tower 354 may be counter-current cooling towers or cross-flow cooling towers. The first heat exchanger 352 may be a double-pipe heat exchanger, such as a plate heat exchanger or a tube heat exchanger. The second chiller 353 may be a screw water chiller, a scroll water chiller, or a centrifugal water chiller. Specifically, an input end of the first cooling tower 351 is connected to the output end of the high-temperature transmission pipeline 31, an output end of the first cooling tower 351 is connected to a first medium inlet 3521 of the first heat exchanger 352, and a first medium outlet 3522 of the first heat exchanger 352 is connected to the input end of the low-temperature transmission pipeline 32. A second medium inlet 3523 of the first heat exchanger 352 is connected to a cold-side outlet 3532 of the second water chiller 353, and a second medium outlet 3524 of the first heat exchanger 352 is connected to a cold-side inlet 3531 of the second water chiller 353 through a sixth pump 96. In this way, a heat exchange medium output by the second water chiller 353 can exchange heat with a heat exchange medium flowing through the high-temperature transmission pipeline 31 to cool the heat exchange medium transmitted from the high-temperature transmission pipeline 31 for heat dissipation in the data center 20. An input end of the second cooling tower 354 is connected to a hot-side outlet 3534 of the second water chiller 353, and an output end of the second cooling tower 354 is connected to a hot-side inlet 3533 of the second water chiller 353 through a fifth pump 95, so that the circulating cooling of the second water chiller 353 can be realized. By arranging the first cooling tower 351, the first heat exchanger 352, the second water chiller 353 and the second cooling tower 354 in the cooling component 35, it is possible to adapt to the scene that there is no water source around a construction site of the energy comprehensive utilization system, and to realize circulating refrigeration to supplement the cold energy for the data center 20.

Referring to FIG. 4, in the same way as the energy comprehensive utilization system adapted to the first operation condition in FIG. 3, a data center heat exchanger 50 and a first water chiller 41 can also be provided in this embodiment. The data center heat exchanger 50 is connected between the heat exchange medium outlet 202 and the heat exchange medium inlet 201 of the data center 20. The first water chiller 41 is connected to the data center heat exchanger 50 and the condenser 123. Under the energy storage subsystem shutdown condition, a heat exchange medium output from the data center 20 is divided into two paths, one path enters the cooling component 35 and is cooled by a cold energy provided by the second water chiller 353, and the other path enters the data center heat exchanger 50 and is cooled by a cold energy provided by the first water chiller 41. The condenser 123 is used to: under the operation condition and in an energy storage stage, condense carbon dioxide by using the cold energy provided by the first water chiller 41. For the specific arrangement and connection manners of the data center heat exchanger 50 and the first water chiller 41, please refer to the description in the previous embodiment, which will not be repeated herein.

Thus, the control method for the energy comprehensive utilization system can include: under the second operation condition and in the energy storage stage, condensing, by the condenser 123, carbon dioxide by using the cold energy provided by the first water chiller 41; and under the energy storage subsystem shutdown condition, using, by the data center heat exchanger 50, the cold energy provided by the first water chiller 41 and the cooling component 35 to cool the heat exchange medium output from the data center 20.

In some embodiments, under the energy storage subsystem shutdown condition, the cold energy provided by the first water chiller 41 can ensure that the heat dissipation demand of the data center 20 can be met, and it can adapt to various working conditions.

In some embodiments, referring to FIG. 3 and FIG. 4, the energy comprehensive utilization system of the disclosure further includes a branch pipeline 61. An inlet end of the branch pipeline 61 is connected to an outlet of the compressor 1211 of the compression energy storage part 121, and an outlet end of the branch pipeline 61 is connected to an inlet of an expander 1432 of the expansion energy release part 143. The branch pipeline 61 is provided with a working fluid flow regulating valve 62 thereon. By setting the branch pipeline 61, heat from a part of high-temperature and high-pressure gaseous carbon dioxide output from the outlet of the compressor 1211 can be stored by the first heat storage unit 1212 and the part of the high-temperature and high-pressure gaseous carbon dioxide is condensed into high-pressure liquid carbon dioxide by the condenser 123, to thereby store energy in the form of a heat energy and a compression energy, and the other part of the high-temperature and high-pressure gaseous carbon dioxide can directly enter the expander 1432 through the branch pipeline 61 for expansion to perform work and thus generate electricity. Therefore, the control method for the energy comprehensive utilization system can include: under the operation condition and in the energy storage stage, opening the working fluid flow regulating valve 62 to make a part of the carbon dioxide output by the compressor 1211 of the compression energy storage part 121 enter the condenser 123 for condensation, and the other part of the carbon dioxide is input through the branch pipeline 61 to an inlet of the expander 1432 of the expansion energy release part 143 for expansion to perform work.

Compared with embodiments without the branch pipeline 61, in the energy comprehensive utilization system and the control method provided by this embodiment, only part of the carbon dioxide output by the compressor 1211 is stored in the liquid storage unit 13, so a required volume of the liquid storage unit 13 is reduced, which can reduce the construction investment cost of the liquid storage unit 13, and ensure that a part of the carbon dioxide needs to be evaporated by the evaporator 141, so that the heat of the data center 20 can be dissipated by the evaporator 141. Compared with the embodiment without the branch pipeline 61, a part of the carbon dioxide output by the compressor 1211 can directly enter the expander 1432 to expand to perform work, which can reduce the energy loss of carbon dioxide flowing through various devices and improve the power generation efficiency. Because a power generation period of green power sources such as wind power and solar power is unstable due to the influence of site climate and environment, it can not meet the 24-hour operation demand of the data center. In this embodiment, the motor connected to the compressor 1211 can be connected to the green power sources such as wind power and solar power generation, and the carbon dioxide output by the compressor 1211 can be converted into stable electric energy to provide stable electric energy for the data center 20, whether the carbon dioxide enters the liquid storage unit 13 or directly enters the expander 1432 through the branch pipeline 61 to perform work. An opening of the working fluid flow regulating valve 62 can be adjusted according to a duration of the energy storage stage to ensure that the evaporator 141 can work normally to dissipate heat for the data center 20 and the power generation efficiency is improved as much as possible.

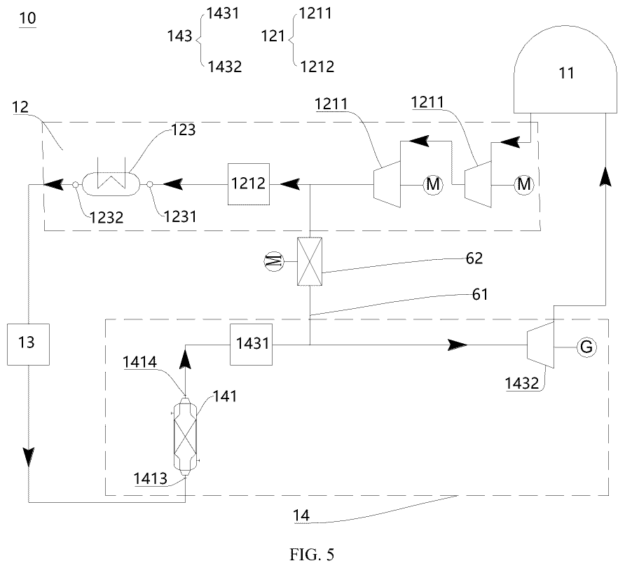

In some embodiments, when the compression energy storage part 121 includes a multi-stage compressor 1211, the inlet end of the branch pipeline 61 is connected to an outlet of a last-stage compressor 1211 in the multi-stage compressor 1211. FIG. 5 illustrates an embodiment in which the compression energy storage part 121 includes a two-stage compressor 1211, and the inlet end of the branch pipeline 61 is connected to an outlet of the second-stage compressor 1211, so that more power generation can be obtained and the power generation efficiency and energy utilization rate can be improved.

In some embodiments, the opening of the working fluid flow regulating valve 62 can be adjusted according to a power generation of the expander 1432. The specific control method is as follows: in the energy storage stage, the working fluid flow regulating valve 62 is adjusted to make a mass flow of carbon dioxide passing through the branch pipeline 61 satisfy the following relationship:

$$m = \frac{W}{Δ H}$$

where m represents the mass flow (in units of kg/s) of the carbon dioxide passing through the branch pipeline 61, W represents the power generation (in units of kJ/s) of the expander 1432 of the expansion energy release part 143, and ΔH represents an enthalpy difference (in units of kJ/kg) between the inlet of the expander 1432 and an outlet of the expander 1432.

For example, as described in the previous embodiments, the generator connected with the expander 1432 is connected to the power input end of the data center 20 to supply power to the data center 20, so the power generation W of the expander 1432 in this embodiment can be determined according to the power demand of the data center 20, so as to ensure that that the power generation W of the expander 1432 meets the normal operation of the data center 20. The enthalpy difference ΔH between the inlet and the outlet of the expander 1432 can be calculated according to an inlet temperature and pressure of the expander 1432 and an outlet temperature and pressure of the expander 1432. By adjusting the working fluid flow regulating valve 62 in the above way, during the energy storage stage, a part of carbon dioxide can directly enter the expander 1432 from the outlet of the compressor 1211 to perform work and generate electricity, and the remaining carbon dioxide enters the liquid storage unit 13 to achieve energy storage. All the carbon dioxide input to the expander 1432 during the energy storage stage comes from the branch pipeline 61, which can improve the power generation efficiency, meet the power demand of the data center 20 and reduce the waste of energy.

In some embodiments, the opening of the working fluid flow regulating valve 62 can be adjusted according to the duration of the energy storage stage, and a specific control method is as follows: in the energy storage stage, the working fluid flow regulating valve 62 is adjusted so that a relationship between a mass flow of carbon dioxide passing through the branch pipeline 61 and a mass flow of carbon dioxide output by the compressor 1211 of the compression energy storage part 121 satisfies the following relationship:

$${Q}_{1} \leq \frac{{Q}_{2} \times {T}_{1}}{24}$$

where Q₁ represents the mass flow of the carbon dioxide passing through the branch pipeline, Q₂ represents the mass flow of the carbon dioxide output by the compressor of the compression energy storage part, and T₁ represents the duration of the energy storage phase.

Specifically, if the motor of the compressor 1211 is only connected to a municipal power grid, the duration of the energy storage phase is a local valley power period, which can be determined according to a local peak-valley power consumption policy. For example, if the local valley power period is 6 hours, the mass flow Q₁ of the carbon dioxide passing through the branch pipeline is less than or equal to a quarter of the mass flow Q₂ of the carbon dioxide output by the compressor of the compression energy storage part. When Q₁ is equal to a quarter of Q₂, the power generation efficiency can be maximized and the evaporator 141 can be ensured to continuously dissipate heat for the data center 20.

In some embodiments, if the motor of the compressor 1211 is connected to the municipal power grid and also connected to green power sources such as wind power and solar power generation, the duration of the energy storage phase can be determined according to a power generation duration of the green power sources and the local valley power period, and then the opening of the working fluid flow regulating valve 62 can be determined.

For example, the opening of the working fluid flow regulating valve 62 can also be adjusted directly according to the local valley power period, to make Q₁ satisfy the following formula:

$${Q}_{1} \leq \frac{{Q}_{2} \times {T}_{2}}{24}$$

where T₂ represents the local valley power period.

In some embodiments of the disclosure, a rated mass flow of the compressor 1211 and a rated mass flow of the expander 1432 in the energy storage subsystem 10 can also be designed according to the local valley power period or the duration of the energy storage phase. For example, the rated mass flow of the expander 1432 and the rated mass flow of the compressor 1211 satisfy the following relationship:

$${Q}_{3} = \frac{{Q}_{4} \times {T}_{1}}{24}$$

where Q₃ represents the rated mass flow of the expander 1432, Q₄ represents the rated mass flow of the compressor 1211, and T₁ represents the duration of the energy storage stage. Specifically, if the motor of the compressor 1211 is only connected to a municipal power grid, the duration of the energy storage phase is a local valley power period, which can be determined according to a local peak-valley power consumption policy. For example, if the local valley power period is 6 hours, the rated mass flow of the expander 1432 is a quarter of that of the compressor 1211. By reasonably setting the rated mass flow of the expander 1432 and the rated mass flow of the compressor 1211, the energy release stage can be guaranteed to operate 24 hours a day, and each of the expander 1432 and the compressor 1211 can operate under the rated mass flow as much as possible, so that the equipment selection is more reasonable and the power generation efficiency is higher. In some embodiments, if the motor of the compressor 1211 is connected to the municipal power grid and also connected to green power sources such as wind power and solar power generation, the duration of the energy storage stage can be determined according to a power generation duration of the green energy sources and the local valley power period. For example, the rated mass flow of the expander 1432 and the rated mass flow of the compressor 1211 satisfy the following relationship:

$${Q}_{4} \geq {Q}_{3} \geq \frac{{Q}_{4} \times {T}_{2}}{24}$$

where Q₃ represents the rated mass flow of the expander 1432, Q₄ represents the rated mass flow of the compressor 1211, and T₂ represents the local valley power period. By setting the relationship of rated mass flows above, the selection of the compressor 1211 and the expander 1432 can be more appropriate, thereby saving equipment investment cost and ensuring power generation efficiency.

An operation principle and a flow of the energy comprehensive utilization system shown in FIG. 3 and FIG. 4 will be specifically illustrated below.

When the energy comprehensive utilization system as shown in FIG. 3 is under the first operation condition, in the energy storage stage, the working fluid flow regulating valve 62 of the energy storage subsystem 10 is opened, and gaseous carbon dioxide in the gaseous carbon dioxide management unit 11 is first input into the compressor 1211 and compressed into high-temperature and high-pressure gaseous carbon dioxide. Then, an opening of the working fluid flow regulating valve 62 is adjusted, so that a part of the gaseous carbon dioxide output by the compressor 1211 enters the first heat storage unit 1212, and heat is absorbed and stored by the first heat storage unit 1212. The other part of the gaseous carbon dioxide output by the compressor 1211 directly enters the expander 1432 via the branch pipeline 61 to perform work and generate electricity, and provides electricity for the data center 20. Low-temperature gaseous carbon dioxide output from the first heat storage unit 1212 enters the condenser 123, the sixth valve 86 and the seventh valve 87 are closed, the eighth valve 88 and the ninth valve 89 are opened, and the first water chiller 41 and the heat pump unit 33 are started to provide a cold energy for the condenser 123 to condense the gaseous carbon dioxide into liquid carbon dioxide and store the liquid carbon dioxide in the liquid storage unit 13. At the same time, a low-temperature heat exchange medium stored in the low-temperature medium storage unit 342 is heated to a high-temperature heat exchange medium by the heat pump unit 33 and then transported to the high-temperature medium storage unit 341 for storage. The third cooling tower 42 provides a heat dissipation medium to the first water chiller 41 through the third pump 93 for heat dissipation. The energy release stage operates 24 hours a day. In the energy release stage, the third valve 83 and the fifth valve 85 are closed, and the second valve 82 and the fourth valve 84 are opened. The liquid carbon dioxide stored in the liquid storage unit 13 enters the evaporator 141 to absorb heat and warms up to convert into gaseous carbon dioxide, and then the gaseous carbon dioxide passes through the second heat storage unit 1431 to absorb heat to become high-temperature gaseous carbon dioxide. Then, the high-temperature gaseous carbon dioxide enters the expander 1432 to perform work and generate electricity, and the gaseous carbon dioxide after performing work returns to the gaseous carbon dioxide management unit 11 for storage. The first pump 91 is started to realize the circulation of the heat exchange medium between the evaporator 141 and the data center 20. A path of a heat exchange medium output by the first pump 91 enters the data center 20 to realize the heat dissipation of the data center 20, and the other path of the heat exchange medium output by the first pump 91 is transmitted to the low-temperature medium storage unit 342 for storage through the low-temperature transmission pipeline 32. According to the heat required by the evaporator 141, the flow rate of the first pump 91 and the opening of the first valve 81 are controlled, and the flow rate of the heat exchange medium transported from the high-temperature medium storage unit 341 to the evaporator 141 through the high-temperature transmission pipeline 31 is controlled, so that the heat exchange medium output through the high-temperature transmission pipeline 31 and the heat exchange medium output from the data center 20 can flow into the evaporator 141 together to meet the heat demand of the evaporator 141.

When the energy storage subsystem 10 needs to be maintained and overhauled, it enters the energy storage subsystem shutdown condition, and the working fluid flow regulating valve 62, the first valve 81, the second valve 82, the fourth valve 84, the eighth valve 88 and the ninth valve 89 are closed, and the third valve 83, the fifth valve 85, the sixth valve 86 and the seventh valve 87 are opened. The heat pump unit 33 and/or the first water chiller 41 is/are started to provide a cold energy for the data center heat exchanger 50, and the cold energy exchanges heat with the heat exchange medium output by the data center 20, to cool the data center 20. When the heat pump unit 33 is started, the heat exchange medium stored in the low-temperature medium storage unit 342 is heated and then transported to the high-temperature medium storage unit 341 for storage. When the first water chiller 41 is started, the third cooling tower 42 is also started to convey a heat dissipation medium to the first water chiller 41 to dissipate heat for the first water chiller.

A water supply device 70 is connected between the heat exchange medium outlet 1412 of the evaporator 141 and the heat exchange medium inlet 201 of the data center 20. During the operation of the energy comprehensive utilization system, the water supply device 70 is used to supplement the heat exchange medium to ensure the sufficiency of the heat exchange medium.

When the energy comprehensive utilization system as shown in FIG. 4 is under the second operation condition, in the energy storage stage, the working fluid flow regulating valve 62 of the energy storage subsystem 10 is opened, and gaseous carbon dioxide in the gaseous carbon dioxide management unit 11 is first input into the compressor 1211 and compressed into high-temperature and high-pressure gaseous carbon dioxide. Then, an opening of the working fluid flow regulating valve 62 is adjusted, so that a part of the gaseous carbon dioxide output by the compressor 1211 enters the first heat storage unit 1212, and heat is absorbed and stored by the first heat storage unit 1212. The other part of the gaseous carbon dioxide output by the compressor 1211 directly enters the expander 1432 via the branch pipeline 61 to perform work and generate electricity, and provides electricity for the data center 20. Low-temperature gaseous carbon dioxide output from the first heat storage unit 1212 enters the condenser 123, the sixth valve 86 and the seventh valve 87 are closed, the eighth valve 88 and the ninth valve 89 are opened, and the first water chiller 41 is started to provide a cold energy for the condenser 123 to condense the gaseous carbon dioxide into liquid carbon dioxide and store the liquid carbon dioxide in the liquid storage unit 13. The third cooling tower 42 provides a heat dissipation medium to the first water chiller 41 through the third pump 93 for heat dissipation. The energy release stage operates 24 hours a day. In the energy release stage, the third valve 83 and the fifth valve 85 are closed, and the second valve 82 and the fourth valve 84 are opened. The liquid carbon dioxide stored in the liquid storage unit 13 enters the evaporator 141 to absorb heat and warms up to convert into gaseous carbon dioxide, and then the gaseous carbon dioxide passes through the second heat storage unit 1431 to absorb heat to become high-temperature gaseous carbon dioxide. Then, the high-temperature gaseous carbon dioxide enters the expander 1432 to perform work and generate electricity, and the gaseous carbon dioxide after performing work returns to the gaseous carbon dioxide management unit 11 for storage. The first pump 91 is started to realize the circulation of the heat exchange medium between the evaporator 141 and the data center 20, and the heat exchange medium output by the first pump 91 enters the data center 20 to realize the heat dissipation of the data center 20. A path of the heat exchange medium output by the data center 20 enters the evaporator 141 to provide the required heat for the evaporator 141, and the other path of the heat exchange medium output by the data center 20 is transmitted to the first cooling tower 351 through the high-temperature transmission pipeline 31 for cooling. The second water chiller 353 is started to provide a cold energy for the first heat exchanger 352. The heat exchange medium cooled by the first cooling tower 351 enters the first heat exchanger 352 for cooling, and then is transmitted through the low-temperature transmission pipeline 32 and flows into the data center 20 together with the heat exchange medium output by the evaporator 141 to realize heat dissipation of the data center 20. During the operation of the second water chiller 353, the second cooling tower 354 transports a heat dissipation medium to the second water chiller 353 through the fifth pump 95 and uses the heat dissipation medium to circularly dissipate heat for the second water chiller 353.

When the energy storage subsystem 10 needs to be maintained and overhauled, it enters the energy storage subsystem shutdown condition, and the working fluid flow regulating valve 62, the second valve 82, the fourth valve 84, the eighth valve 88 and the ninth valve 89 are closed, and the third valve 83, the fifth valve 85, the sixth valve 86 and the seventh valve 87 are opened. The first water chiller 41 is started to provide a cold energy for the data center heat exchanger 50. A part of the heat exchange medium output by the data center 20 enters the data center heat exchanger 50 for heat exchange and cooling, and the other part of the heat exchange medium output by the data center 20 sequentially enters the first cooling tower 351 and the first heat exchanger 352 through the high-temperature transmission pipeline 31 for cooling, and then passes through the low-temperature transmission pipeline 32 and finally flows into the heat exchange medium inlet 201 of the data center 20 together with the heat exchange medium output by the data center heat exchanger 50. The first water chiller 41 and the cooling component 35 realize the circulating cooling of the heat exchange medium to dissipate heat for the data center 20.

The water supply device 70 is connected between the heat exchange medium outlet 1412 of the evaporator 141 and the heat exchange medium inlet 201 of the data center 20. During the operation of the energy comprehensive utilization system, the water supply device 70 is used to supplement the heat exchange medium to ensure the sufficiency of the heat exchange medium.

To sum up, the gas-liquid phase change carbon dioxide energy comprehensive utilization system adapted for the data center provided by the embodiments of the disclosure has the following advantages. (1) The evaporator 141 of the energy storage subsystem is coupled with the data center 20, thereby allowing for the simultaneous heating of the evaporator 141 and cooling of the data center 20 through the circulation of the heat exchange medium between the data center 20 and the evaporator 141, so that the construction investment cost of the heating facilities of the evaporator 141 and the heat dissipation facilities of the data center 20 can be reduced, and energy can be realized. (2) The configuration of the heat balance component 30 can ensure the stable operation of the energy comprehensive utilization system in view of the scene that the heat supply required by the evaporator 141 is inconsistent with the heat dissipation of the data center 20. (3) The energy storage subsystem 10 operates in the energy release stage for 24 hours a day, and the generated power is used in the data center 20, which matches the characteristics of the data center 20 operating 24 hours a day and provides a stable and continuous power supply for the operation of the data center 20. (4) Setting up the data center heat exchanger 50 coupled with the first water chiller 41, which can ensure that the data center 20 can still be cooled when the evaporator 141 is shut down, maintaining the stable operation of the data center 20. This eliminates the need for additional backup cooling equipment, reduces investment costs, and is suitable for various operation conditions. (5) Setting the branch pipeline 61 and the working fluid flow regulating valve 62 in the energy storage subsystem 10 can reduce the energy consumption and the volume of the liquid storage unit 13, thus improving the power generation efficiency. (6) The energy storage subsystem 10 is coupled with the green energy sources such as wind power and solar power generation, which can convert the green energy sources into stable power output and provide stable power for the data center 20.

The above is merely the exemplarily embodiment of the disclosure, and does not limit the disclosure in any form. Although the disclosure has been disclosed in the exemplarily embodiment, it is not used to limit the disclosure. Any person familiar with this field can make some changes or modify it into an equivalent embodiment by using the technical content disclosed above without departing from the scope of the technical solution of the disclosure. However, any simple modification, equivalent change and modification of the above embodiment according to the technical essence of the disclosure without departing from the technical scheme of the disclosure still fall within the scope of the disclosure.

What is claimed is:

1. A gas-liquid phase change carbon dioxide energy comprehensive utilization system adapted for a data center, comprising:
an energy storage subsystem, comprising: a gaseous carbon dioxide management unit, an energy storage component, a liquid storage unit, and an energy release component, which are sequentially connected in that order to form a closed loop, wherein the energy storage component comprises a condenser, and the energy storage component is configured to: compress gaseous carbon dioxide output from the gaseous carbon dioxide management unit to obtain compressed gaseous carbon dioxide and condense the compressed gaseous carbon dioxide by the condenser into liquid carbon dioxide for storing in the liquid storage unit; and the energy release component comprises an evaporator, and the energy release component is configured to: evaporate, by the evaporator, the liquid carbon dioxide output from the liquid storage unit into gaseous carbon dioxide, expand the gaseous carbon dioxide to perform work, and store the gaseous carbon dioxide after expanding and performing work in the gaseous carbon dioxide management unit;
the data center, wherein a heat exchange medium inlet of the data center is connected to a heat exchange medium outlet of the evaporator, and a heat exchange medium outlet of the data center is connected to a heat exchange medium inlet of the evaporator; and
a heat balance component, comprising a high-temperature transmission pipeline and a low-temperature transmission pipeline, wherein the high-temperature transmission pipeline is connected between the heat exchange medium outlet of the data center and the heat exchange medium inlet of the evaporator, and the low-temperature transmission pipeline is connected between the heat exchange medium inlet of the data center and the heat exchange medium outlet of the evaporator,
wherein the heat balance component is configured to: when the gas-liquid phase change carbon dioxide energy comprehensive utilization system adapted for the data center is in an operation condition and heat dissipation of the data center is inconsistent with heat supply required by the evaporator, supplement a high-temperature heat exchange medium to the heat exchange medium inlet of the evaporator through the high-temperature transmission pipeline or supplement a low-temperature heat exchange medium to the heat exchange medium inlet of the data center through the low-temperature transmission pipeline.

2. The gas-liquid phase change carbon dioxide energy comprehensive utilization system adapted for the data center as claimed in claim 1, wherein the operation condition comprises a first operation condition; and under the first operation condition, the heat dissipation of the data center is less than the heat supply required by the evaporator;
wherein the heat balance component comprises a heat pump unit; the heat exchange medium inlet of the evaporator is connected to the heat pump unit through the high-temperature transmission pipeline; the heat exchange medium outlet of the evaporator is connected to the heat pump unit through the low-temperature transmission pipeline; and under the first operation condition, a heat exchange medium output from the evaporator to the low-temperature transmission pipeline is heated by the heat pump unit, and then passes through the high-temperature transmission pipeline and finally flows into the evaporator together with a heat exchange medium output from the data center.

3. The gas-liquid phase change carbon dioxide energy comprehensive utilization system adapted for the data center as claimed in claim 2, wherein the heat balance component further comprises a heat exchange medium storage component, and the heat exchange medium storage component comprises a high-temperature medium storage unit disposed on the high-temperature transmission pipeline and a low-temperature medium storage unit disposed on the low-temperature transmission pipeline.

4. The gas-liquid phase change carbon dioxide energy comprehensive utilization system adapted for the data center as claimed in claim 3, wherein a heat exchange medium inlet of the condenser is connected to a cold-side outlet of the heat pump unit, and a heat exchange medium outlet of the condenser is connected to a cold-side inlet of the heat pump unit.

5. The gas-liquid phase change carbon dioxide energy comprehensive utilization system adapted for the data center as claimed in claim 3, wherein the gas-liquid phase change carbon dioxide energy comprehensive utilization system adapted for the data center has an energy storage subsystem shutdown condition; the gas-liquid phase change carbon dioxide energy comprehensive utilization system adapted for the data center further comprises a data center heat exchanger; the data center heat exchanger is connected between the heat exchange medium outlet of the data center and the heat exchange medium inlet of the data center; the data center heat exchanger is connected to the heat pump unit; and the data center heat exchanger is configured to: under the energy storage subsystem shutdown condition, cool the heat exchange medium output from the data center by using a cold energy provided by the heat pump unit.

6. The gas-liquid phase change carbon dioxide energy comprehensive utilization system adapted for the data center as claimed in claim 3, wherein the gas-liquid phase change carbon dioxide energy comprehensive utilization system adapted for the data center has an energy storage subsystem shutdown condition; the gas-liquid phase change carbon dioxide energy comprehensive utilization system adapted for the data center further comprises a data center heat exchanger and a first water chiller; the data center heat exchanger is connected between the heat exchange medium outlet of the data center and the heat exchange medium inlet of the data center; the first water chiller is connected to the data center heat exchanger and the condenser; the data center heat exchanger is configured to: under the energy storage subsystem shutdown condition, cool the heat exchange medium output from the data center by using a cold energy provided by the first water chiller; and the condenser is configured to: under the operation condition and in an energy storage stage, condense the compressed gaseous carbon dioxide by using the cold energy provided by the first water chiller.

7. The gas-liquid phase change carbon dioxide energy comprehensive utilization system adapted for the data center as claimed in claim 1, wherein the operation condition comprises a second operation condition; and under the second operation condition, the heat dissipation of the data center is greater than the heat supply required by the evaporator; and
wherein the heat balance component comprises a cooling component; the heat exchange medium outlet of the data center is connected to the cooling component through the high-temperature transmission pipeline; the heat exchange medium inlet of the data center is connected to the cooling component through the low-temperature transmission pipeline; and under the second operation condition, a heat exchange medium output from the data center to the high-temperature transmission pipeline is cooled by the cooling component, and then passes through the low-temperature transmission pipeline and finally flows into the data center together with a heat exchange medium output from the evaporator.

8. The gas-liquid phase change carbon dioxide energy comprehensive utilization system adapted for the data center as claimed in claim 7, wherein the cooling component comprises a first cooling tower, a first heat exchanger, a second water chiller, and a second cooling tower; the first heat exchanger is connected between the first cooling tower and the low-temperature transmission pipeline; the second water chiller is connected to the first heat exchanger and the second cooling tower; the second water chiller is configured to provide a cold energy for the first heat exchanger; and the second cooling tower is configured to dissipate heat for the second water chiller.

9. The gas-liquid phase change carbon dioxide energy comprehensive utilization system adapted for the data center as claimed in claim 8, wherein the gas-liquid phase change carbon dioxide energy comprehensive utilization system adapted for the data center has an energy storage subsystem shutdown condition; the gas-liquid phase change carbon dioxide energy comprehensive utilization system adapted for the data center further comprises a data center heat exchanger and a first water chiller; the data center heat exchanger is connected between the heat exchange medium outlet of the data center and the heat exchange medium inlet of the data center; the first water chiller is connected to the data center heat exchanger and the condenser; under the energy storage subsystem shutdown condition, the heat exchange medium output from the data center is divided into two paths, one of the two paths enters the cooling component and is cooled down with a cold energy provided by the second water chiller, the other path of the two paths enters the data center heat exchanger and is cooled down with a cold energy provided by the first water chiller; and the condenser is configured to: under the operation condition and in an energy storage stage, condense the compressed gaseous carbon dioxide by using the cold energy provided by the first water chiller.

10. The gas-liquid phase change carbon dioxide energy comprehensive utilization system adapted for the data center as claimed in claim 1, further comprising a branch pipeline, wherein the energy storage component comprises a compression energy storage part; the compression energy storage part is connected between the gaseous carbon dioxide management unit and the condenser; the energy release component comprises an expansion energy release part, and the expansion energy release part is connected between the evaporator and the gaseous carbon dioxide management unit; an inlet end of the branch pipeline is connected to an outlet of a compressor of the compression energy storage part, and an outlet end of the branch pipeline is connected to an inlet of an expander of the expansion energy release part; and a working fluid flow regulating valve is disposed on the branch pipeline.

11. The gas-liquid phase change carbon dioxide energy comprehensive utilization system adapted for the data center as claimed in claim 10, wherein the compression energy storage part comprises multi-stage compressors, and the inlet end of the branch pipeline is connected to an outlet of a last-stage compressor of the multi-stage compressors.

12. A control method, applied to the gas-liquid phase change carbon dioxide energy comprehensive utilization system adapted for the data center as claimed in claim 1, wherein the gas-liquid phase change carbon dioxide energy comprehensive utilization system adapted for the data center comprises the operation condition, and the control method comprises:
under the operation condition and when the heat dissipation of the data center is inconsistent with the heat supply required by the evaporator, supplementing, by the heat balance component, the high-temperature heat exchange medium to the heat exchange medium inlet of the evaporator through the high-temperature transmission pipeline, or supplementing, by the heat balance component, the low-temperature heat exchange medium to the heat exchange medium inlet of the data center through the low-temperature transmission pipeline.

13. The control method as claimed in claim 12, wherein the gas-liquid phase change carbon dioxide energy comprehensive utilization system adapted for the data center has an energy storage subsystem shutdown condition; the gas-liquid phase change carbon dioxide energy comprehensive utilization system adapted for the data center further comprises a data center heat exchanger and a first water chiller; and the control method comprises:
under the operation condition and in an energy storage stage, condensing, by the condenser, the compressed gaseous carbon dioxide by using the cold energy provided by the first water chiller;
under the energy storage subsystem shutdown condition, cooling, by the data center heat exchanger, a heat exchange medium output from the data center by using a cold energy provided by the first water chiller.

14. The control method as claimed in claim 12, wherein the gas-liquid phase change carbon dioxide energy comprehensive utilization system adapted for the data center further comprises a branch pipeline; the energy storage component comprises a compression energy storage part; the compression energy storage part is connected between the gaseous carbon dioxide management unit and the condenser; the energy release component comprises an expansion energy release part, and the expansion energy release part is connected between the evaporator and the gaseous carbon dioxide management unit; an inlet end of the branch pipeline is connected to an outlet of a compressor of the compression energy storage part, and an outlet end of the branch pipeline is connected to an inlet of an expander of the expansion energy release part; and a working fluid flow regulating valve is disposed on the branch pipeline;
wherein the control method comprises: under the operation condition and in an energy storage stage, opening the working fluid flow regulating valve to make a part of carbon dioxide output by the compressor of the compression energy storage part enter the condenser for condensation, and inputting the remaining part of the carbon dioxide output by the compressor of the compression energy storage part via the branch pipeline to an inlet of the expander of the expansion energy release part for expanding to perform work.

15. The control method as claimed in claim 14, further comprising: in the energy storage stage, adjusting the working fluid flow regulating valve to make a mass flow of carbon dioxide passing through the branch pipeline satisfies a relationship as follows:
$$m = \frac{W}{Δ H}$$
where m represents the mass flow of the carbon dioxide passing through the branch pipeline, W represents a power generation of the expander of the expansion energy release part, and ΔH represents an enthalpy difference between the inlet of the expander and an outlet of the expander.
